(19) United States
(12) Patent Application Publication
(10) Pub. No.: US 2001/0014012 A1
(43) Pub. Date: Aug. 16, 2001

(54) Electronic instrument having a heat sink

(76) Inventor: Masaharu Imazato, Tokyo (JP)

Correspondence Address: SUGHRUE, MION, ZINN, MACPEAK & SEAS, PLLC, 2100 Pennsylvania Avenue, N.W., Washington, DC, 20037-3213, US

(21) Appl. No.: 09/739,641

(22) Filed: Dec. 20, 2000

(30) Foreign Application Priority Data
Dec. 22, 1999 (JP) 11-365626

(51) Int. Cl. H05K 7/20

(52) U.S. Cl. 361/709

(57) ABSTRACT

An electronic equipment has a heat sink for radiating heat generated in a CPU operating with a clock signal, and an electromagnetic wave absorber for suppressing the noise generated based on the high-harmonic components of the clock signal and radiated through the heat sink The electromagnetic wave absorber has an area which is ⅓ to ⅔ of the bottom surface of the heat sink opposing the CPU, and is attached at the center of the bottom surface.

### BACKGROUND OF THE INVENTION

(a) Field of the Invention

The present invention relates to an electronic equipment having a heat sink and, more particularly, to an electronic equipment mounting thereon an electronic unit operating with a clock signal, such as a central processing unit (CPU), and an associated heat sink for radiating the heat generated in the electronic unit.

(b) Description of a Related Art

An electronic equipment, such as personal computer or workstation, mounting thereon a CPU operating with a clock signal generally consumes a higher amount of operational current along with a higher operational speed thereof. For suppressing the temperature rise of the CPU, the electronic equipment has a heat sink (radiator) in association with the CPU to thereby maintain the temperature of the CPU below an allowable level.

Referring to FIG. 1, a conventional electronic equipment 10 includes a printed circuit board (PCB) 11, a CPU 12 mounted thereon via a connector assembly 13, and a heat sink 15 disposed on the CPU 12. The heat sink 15 includes a radiation plate 16 attached onto the top of the CPU 12, and a plurality of fins or radiation pillars 17 extending in the vertical direction from the top of the radiation plate 16. Most of the heat generated in the CPU 12 is radiated from the heat sink 15 to lower the temperature rise of the CPU 12.

The heat sink 15 may be formed as a planar heat sink instead of having the plurality of fins or radiation pillars 17, as in the case of a heat sink provided for a notebook type personal computer.

The recent, remarkable increase of the operational frequency of the CPU 12 for achieving a higher operational speed necessitates larger dimensions of the heat sink 15 in the electronic equipment 10. Especially, in the case of the notebook type personal computer, the housing of the printed circuit board itself is used as the radiation plate in view of achieving larger dimensions for the radiation plate and smaller overall dimensions.

In the electronic equipment having such a heat sink and operating with a high-frequency clock signal, there is a problem in that the heat sink radiates therefrom high-frequency noise having frequencies depending on the clock frequency. Especially, in the case of the notebook type personal computer, the housing of the PCB acting as a radiation plate may satisfy the resonance condition with the high-harmonic frequency components due to specific dimensions thereof, as detailed below.

Referring to FIG. 2 showing a model of the resonance in the radiation plate 16 of the conventional electronic equipment having a specific length, noise current I₀ and noise voltage V₀ are plotted along the longitudinal direction of the radiation plate 16.

It is assumed that the dimension (L1) of the longitudinal direction of the radiation plate 16 is as large as 15 centimeters (cm), that the fundamental frequency of the clock signal is 100 MHz and that the high-harmonic wave components of the clock signal include a frequency component of 1 GHz, i.e., ten times the fundamental frequency. The large length (15 cm) for the radiation plate is employed in view that the radiation plate achieves a higher radiation function without the radiation fins.

In the above assumption, if the frequency component of 1 GHz is transferred through electrostatic coupling to the radiation plate 16, the half wavelength of the noise wave assumes 15 cm, which coincides with the length L1 of the radiation plate 16. Thus, noise is intensified by resonance of the radiation plate 16 with the high-harmonic frequency component.

In the resonance, since both the ends of the radiation plate 16 are open, the noise voltage assumes a maximum V₀ₘₐₓ at both the ends of the radiation plate 16 and the noise current assumes a maximum I₀ₘₐₓ at the center of the radiation plate 16.

It is to be noted that the frequency component of 1 GHz causes a resonance in the case of radiation plate 16 having a length of 15 cm, wherein the radiation plate 16 acts as a half-wavelength antenna to radiate the noise component of 1 GHz.

Other noise components in the clock signal each having a frequency of an integral multiple of the fundamental frequency may be also radiated from the radiation plate 16 as noise radiation by resonance, similarly to the above example, if the resonance condition is satisfied.

In short, resonance in the frequency components of the clock signal with the radiation plate generates strong noise radiation, which may cause the electronic equipment to violate the noise regulation prescribed for information processing devices.

Laid-Open Patent Publication JP-11-121976 describes an integrated circuit having a thermal radiation structure including an electromagnetic wave absorber, a metallic plate, an insulator film and a heat sink which are layered one on another. This technique suppresses noise radiation from the electronic equipment. However, the publication is silent as to the minimum dimensions of the electromagnetic wave absorber with respect to the thermal plate for effectively preventing the noise radiation with minimum cost and necessary space.

Laid-Open Patent Publication JP-11-50029 describes an electronic part wherein the coupling interface between the electronic part and a thermal radiation plate is bonded with an adhesive made of electromagnetic wave absorber for suppressing noise radiation. This technique is also silent to the dimensions of the wave absorber and a suitable shape thereof.

Patent Publication JP-2828059 describes a mounting structure wherein an EMI (electromagnetic interference) gasket is interposed between a heat sink and a PWB for suppressing the noise radiation. This technique is also silent to the dimensions of the wave absorber.

### SUMMARY OF THE INVENTION

In view of the above, it is an object of the present invention to provide an electronic equipment having an electronic unit, such as CPU, operating with a clock signal and an associated heat sink, which is capable of reducing the dimensions of the wave absorber while effectively suppressing the noise radiation.

The present invention provides an electronic equipment including an electronic unit operating with a clock signal, a heat sink having a bottom surface opposing the electronic unit for receiving heat generated by the electronic unit to radiate the heat from the heat sink, and an electromagnetic wave absorber (wave absorber) sheet interposed between the electronic unit and the bottom surface of the heat sink, the wave absorber sheet having an area which is equal to or larger than one-third of the bottom surface.

In accordance with the electronic equipment of the present invention, the noise radiation from the electronic unit can be effectively absorbed by the electromagnetic wave absorber with a suitable size thereof in the case of generation of resonance, whereby the cost and/or space for the wave absorber can be reduced substantially without hindering the thermal conduction from the electronic unit to the heat sink.

The above and other objects, features and advantages of the present invention will be more apparent from the following description, referring to the accompanying drawings.

### BRIEF DESCRIPTION OF THE DRAWINGS

FIG. 1 is a side view of a conventional electronic equipment.

FIG. 2 is a schematic diagram showing the resonance model of the radiation plate in the electronic equipment of FIG. 1.

FIG. 3 is a side view of an electronic equipment according to a first embodiment of the present invention.

FIG. 4 is a perspective view of the radiation plate in the electronic equipment of FIG. 3.

FIG. 5 is a graph showing the noise radiation plotted against the frequency of the noise.

FIG. 6 is a graph showing reduction of the noise radiation plotted against the thickness of the wave absorber.

FIG. 7 is a side view of an electronic equipment according to a second embodiment of the present invention.

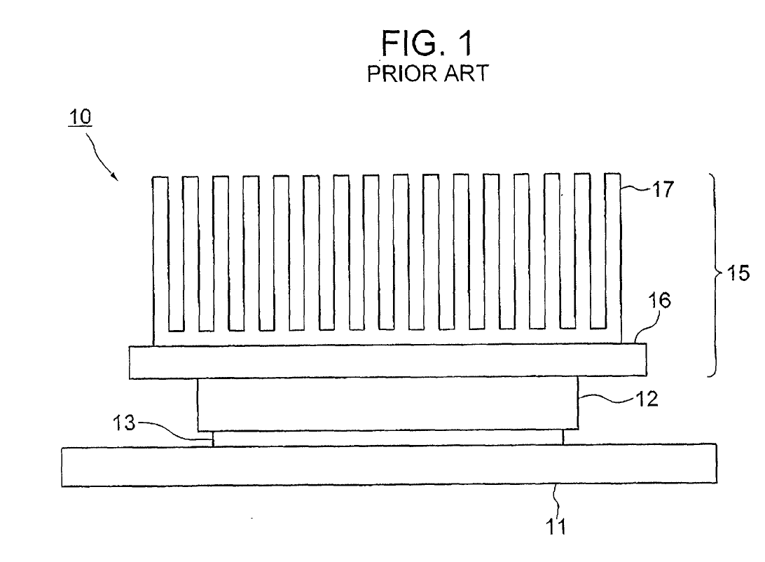

### PREFERRED EMBODIMENTS OF THE INVENTION

Now, the present invention is more specifically described with reference to accompanying drawings, wherein similar constituent elements are designated by similar reference numerals throughout the drawings.

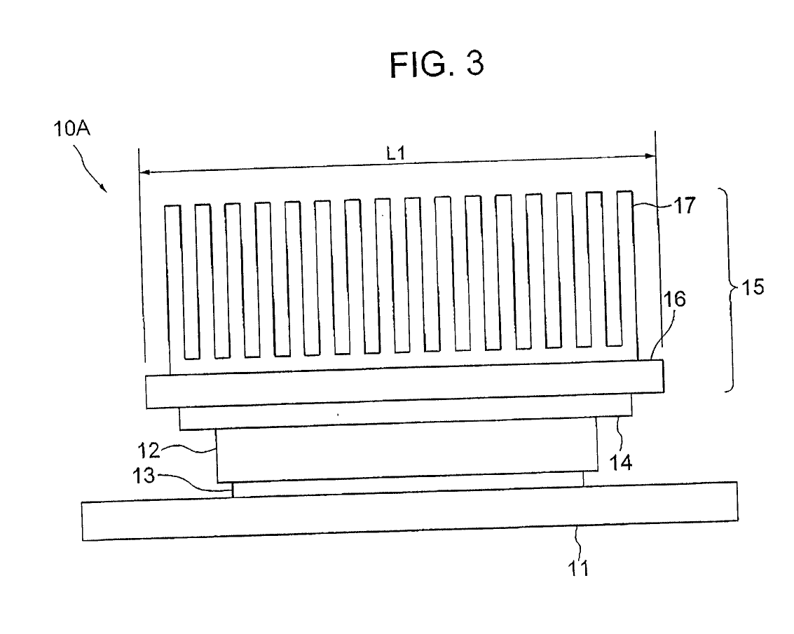

Referring to FIG. 3, an electronic equipment, generally designated by numeral 10A, according to a first embodiment of the present invention includes a PWB 11, a CPU 12 mounted on the PWB 11 via a connector assembly 13, a heat sink 15 mounted on the CPU 12 with an intervention of an electromagnetic wave absorber (hereinafter referred to as simply wave absorber) 14.

The heat sink 15 includes a radiation plate 16 having a thin rectangular shape, and a plurality of radiation pillars (or fins) 17 extending in the vertical direction from the top surface of the radiation plate 16. The radiation plate 16 and the radiation pillars 17 are made of a substance having a high thermal conductivity such as aluminum, and are formed in a unitary body. The plurality of radiation pillars 17 may be omitted, especially in the case of a notebook type personal computer, for smaller dimensions of the electronic equipment.

The wave absorber 14 is formed as a rectangular sheet. The wave absorber 14 is made of a substance including a magnetic material, interposed between the CPU 12 and the radiation plate 16, and covers a part of or the substantially entire surface of the bottom surface of the radiation plate 16. The wave absorber 14 is bonded onto the CPU 12 and the radiation plate 16 by an adhesive. In an alternative, the wave absorber 14 may be sandwiched without an adhesive between the CPU 12 and the radiation plate 16, which are coupled by screws.

In general, the CPU 12 has a clock circuit for generating and transmitting a clock signal, which synchronizes the operation of a variety of processing circuits. The clock signal includes a fundamental frequency component and high-harmonic frequency components. The clock signal including the high-harmonic frequency components is transferred from the CPU 12 to the radiation plate 16 through the electrostatic coupling therebetween, and emitted to the air through the radiation plate 16 and the radiation pillars 17.

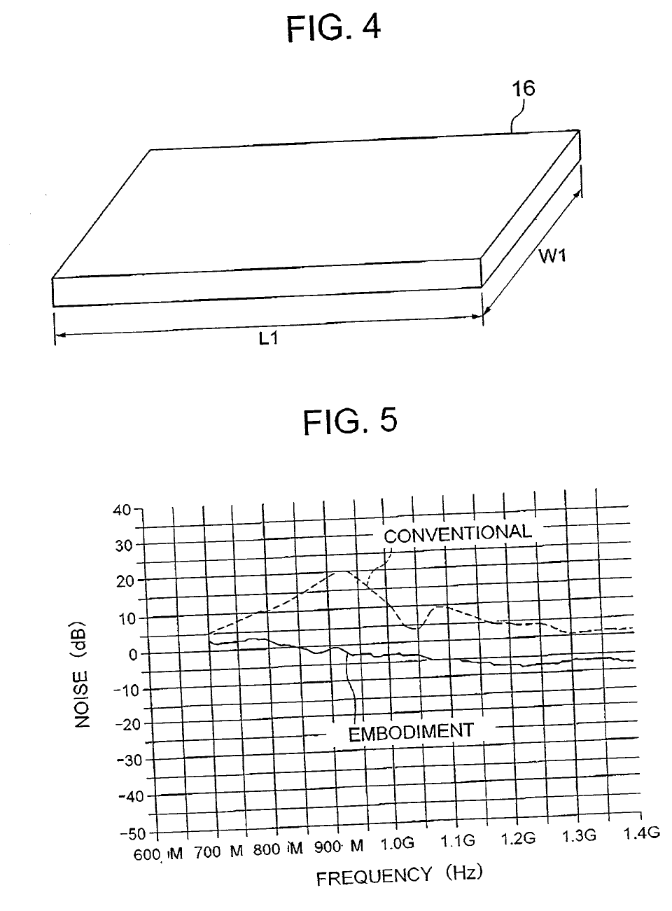

Referring to FIG. 4, the radiation plate 16 has a rectangular shape, which is “L1” long and “W1” wide. It is generally preferable that the dimensions L1 and W1 do not coincide with half the wavelength of each of the high-harmonic frequency components of the clock signal. However, these dimensions may sometimes coincide with half the wavelength of these frequency components due to the restriction for smaller overall dimensions of the electronic equipment, for example.

If the clock signal has a fundamental frequency of 100 MHz and a high-harmonic frequency component of 1 GHz, then a length of 15 cm for L1 coincides with half the wavelength of the high-harmonic component of 1 GHZ to satisfy the resonance condition.

In the present embodiment, the wave absorber 14 disposed between the CPU 12 and the radiation plate 16 suppresses the possible resonance, which may occur under such a resonance condition.

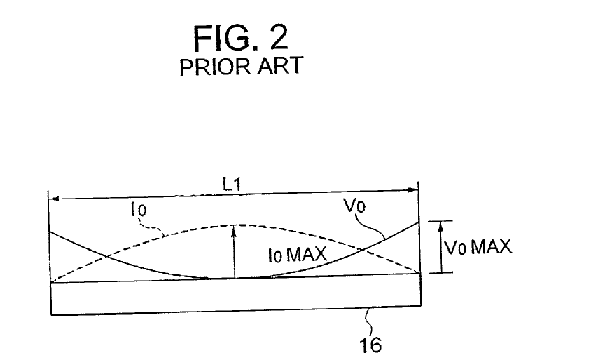

More specifically, the wave absorber 14 reduces the current I₀ shown in FIG. 2 to suppress the resonance and thus the noise radiation, if the resonance condition itself is satisfied.

In the above embodiment, the wave absorber 14 covers substantially the entire bottom surface of the radiation plate 16. A variety of experiments revealed that it is sufficient that the wave absorber 14 cover one-third or more of the entire bottom surface of the radiation plate for effectively suppressing the noise radiation at the center of the bottom surface, when the above resonance condition is satisfied.

When the wave absorber 14 covers one-third of the bottom surface of the radiation plate 16, other part of the bottom surface which opposes the top surface of the CPU 12 is preferably covered by an adhesive layer having a higher thermal conductivity compared to the wave absorber, or the radiation plate 16 may itself directly contact the CPU 12. The latter configuration can be obtained by forming a depression on the bottom surface of the radiation plate 16.

Referring to FIG. 5, there is shown the effect of the wave absorber 14 of the present embodiment in the above condition, wherein the noise radiation in the case of no heat sink is expressed on the zero decibel level. FIG. 5 shows increase of the noise radiation caused by the radiation plate satisfying a resonance condition at a frequency of 1 GHz.

In FIG. 5, the dotted line shows the noise radiation in the conventional electronic equipment having the radiation plate and no wave absorber. The solid line shows the noise radiation in the present embodiment wherein a 0.6-mm-thick wave absorber 14 covered one-third of the entire bottom surface of the radiation plate. The measurement of noise radiation was conducted for a frequency range between 700 MHz and 1.4 GHz.

As understood from FIG. 5, provision of the radiation plate increases the noise radiation by 20 decibel at the maximum in the conventional equipment. Provision of the wave absorber covering one-third of the entire bottom surface of the radiation plate reduced the noise radiation below the zero decibel at the resonance frequency. On the hand, provision of another wave absorber covering one-fourth of the bottom surface could not suppress the noise radiation to zero decibel.

Provision of other wave absorbers covering half, two-third and entire surface of the bottom surface effectively suppressed the noise radiation, with increased degree of suppression in the recited order, although the increase of the noise suppression was moderate from the case of the half to the case of the entire surface. Thus, it is preferable that the wave absorber cover the bottom surface of the radiation plate between one-third and two-third thereof, and more preferably between one-third to half thereof, with other part of the bottom surface opposing the top surface of the CPU 12, if there is such, being in direct contact with the CPU or in contact with the CPU via an adhesive layer having a higher thermal conductivity compared to the wave absorber.

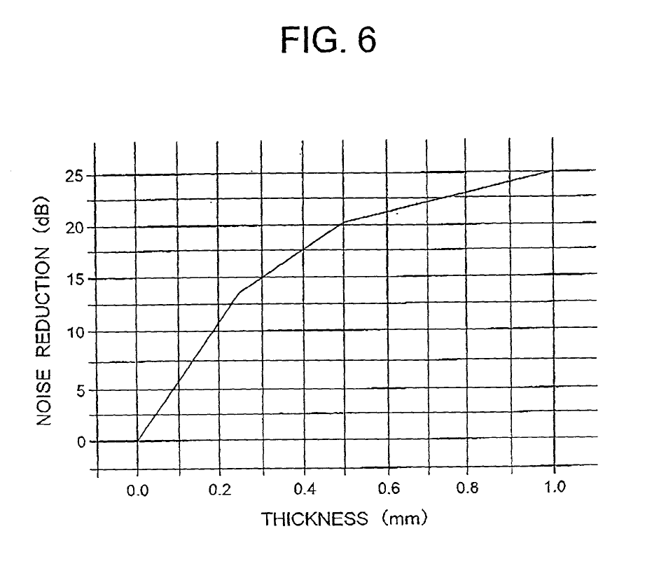

Referring to FIG. 6, there is shown the effect of the noise reduction depending on the thickness of the wave absorber 14 under the condition as recited in connection with FIG. 6. The measurement was conducted at a frequency of 0.92 MHz, while changing the thickness of the wave absorber between 0 mm and 1.0 mm. The measurement was also conducted at a frequency of 1.0 MHz and revealed similar results, although it is not specifically shown in the figure. The reduction of noise radiation monotonically increases with the increase of the thickness of the wave absorber from 0 mm to 1.0 mm

The results reveal that the wave absorber preferably has a thickness of 0.5 mm or more, and more preferably 1.0 or more for suppression of the noise radiation.

As described above, the area of the wave absorber 14 may be reduced down to one-third of the bottom surface of the radiation plate 16, which reduces the cost and space for the wave absorber and/or may increase the thermal conductivity from the CPU 12 to the heat sink. In this case, the wave absorber 14 should be disposed in the central area of the bottom surface of the radiation plate 16 in view that the noise current assumes a maximum at the center of the bottom surface, as understood from FIG. 2. The wave absorber 14 may be prepared by dispersing powder of a magnetic material, such as ferrite, in an adhesive paste.

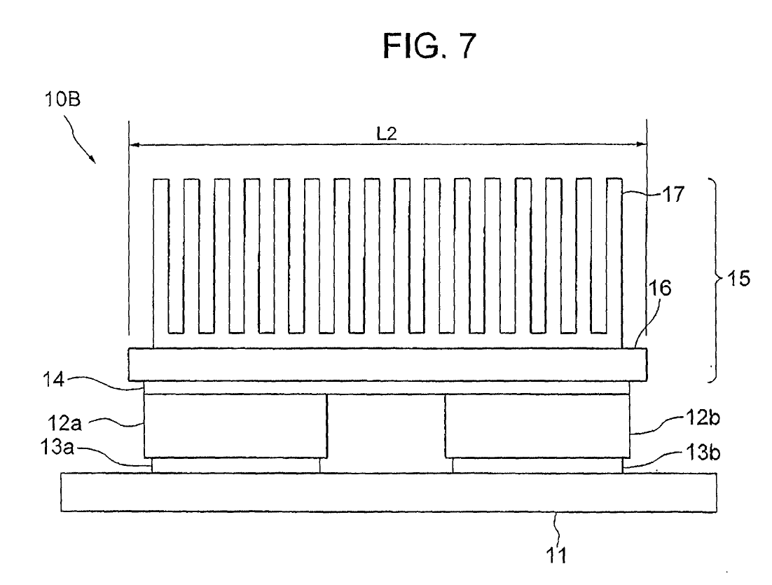

Referring to FIG. 7, an electronic equipment, generally designated by numeral 10B, according to a second embodiment of the present invention includes a pair of CPUs 12a and 12b mounted on the PWB 11 via respective connector assemblies 13a and 13b. A common wave absorber 14 and a common heat sink 15 are disposed for the CPUs 12a and 12b. Other configuration is similar to the configuration shown in FIG. 2.

The common wave absorber 14 and the common heat sink 15 reduce the cost for the electronic equipment. The CPU 12a may be replaced by a memory device, such as a cash memory, or other electronic unit. This configuration may be preferably employed in an IC card for achieving cost reduction, smaller dimensions, smaller thickness and smaller weight.

Since the above embodiments are described only for examples, the present invention is not limited to the above embodiments and various modifications or alterations can be easily made therefrom by those skilled in the art without departing from the scope of the present invention

What is claimed is:

1. An electronic equipment comprising an electronic unit operating with a clock signal, a heat sink having a bottom surface opposing said electronic unit for receiving heat generated by said electronic unit to radiate the heat from the heat sink, and an electromagnetic wave absorber (wave absorber) sheet interposed between said electronic unit and said bottom surface of said heat sink, said wave absorber sheet having an area which is equal to or larger than one-third of said bottom surface.

2. The electronic equipment as defined in claim 1, wherein said area of said wave absorber sheet is equal to or smaller than two-third of said bottom surface.

3. The electronic equipment as defined in claim 2, wherein said wave absorber sheet is disposed at a central area of said bottom surface.

4. The electronic equipment as defined in claim 1, wherein said area of said waver absorber sheet is equal to or smaller than half said bottom surface.

5. The electronic equipment as defined in claim 4, wherein said wave absorber sheet is disposed at a central area of said bottom surface.

6. The electronic equipment as defined in claim 1, wherein said clock signal includes a high-harmonic frequency component having a frequency equal to or higher than 1 GHz and said wave absorber sheet has a thickness of 0.5 mm or more.

7. The electronic equipment as defined in claim 1, further comprising another electronic unit operating with said clock signal, and said wave absorber sheet and said heat sink are provided in common to said electronic unit and said another electronic unit.
